(19) United States
(12) Patent Application Publication
(10) Pub. No.: US 2025/0284190 A1
(43) Pub. Date: Sep. 11, 2025

(54) DETERMINING MASK RULE CHECK VIOLATIONS AND MASK DESIGN BASED ON LOCAL FEATURE DIMENSION

(71) Applicant: ASML NETHERLANDS B.V., Veldhoven (NL)

(72) Inventor: Xingyue PENG, San Jose, CA (US)

(73) Assignee: ASML NETHERLANDS B.V., Veldhoven (NL)

(21) Appl. No.: 18/859,950

(22) PCT Filed: Jul. 12, 2023
(86) PCT No.: PCT/EP2023/069410

§ 371 Date: Oct. 24, 2024

Related U.S. Application Data
(60) Provisional application No. 63/389,137, filed on Jul. 14, 2022.

(51) Int. Cl. G03F 1/36; G01B 21/20; G03F 7/00

(52) U.S. Cl. CPC G03F 1/36; G01B 21/20; G03F 7/70441; G03F 7/705; G03F 7/70508; G03F 7/70516

(57) ABSTRACT

Methods and systems for determining mask rule check (MRC) violations associated with mask features based on a local feature dimension (LFD) of mask features. A detector is placed at a first location of a mask feature and its size is varied until it is in contact with a second location of the mask feature. The size of the detector when it is in contact with the second location is determined as an LFD of a portion of the mask feature. For example, the LFD may be determined as a function of a radius of a circular detector. An MRC violation may be detected by comparing the LFD with an LFD specification in the MRC. For example, an MRC violation may be detected when the LFD of the portion is lesser than a minimum LFD or greater than a maximum LFD specified in the MRC.

### CROSS-REFERENCE TO RELATED APPLICATIONS

This application claims priority of U.S. application 63/389,137 which was filed on Jul. 14, 2022 and which is incorporated herein in its entirety by reference.

### TECHNICAL FIELD

The description herein relates to a mechanism for determining mask rule check violations and mask design for photolithography masks to be employed in in semiconductor manufacturing.

### BACKGROUND

A lithographic projection apparatus can be used, for example, in the manufacture of integrated circuits (ICs). In such a case, a patterning device (e.g., a mask) may contain or provide a circuit pattern corresponding to an individual layer of the IC (“design layout”), and this circuit pattern can be transferred onto a target portion (e.g. comprising one or more dies) on a substrate (e.g., silicon wafer) that has been coated with a layer of radiation-sensitive material (“resist”), by methods such as irradiating the target portion through the circuit pattern on the patterning device. In general, a single substrate contains a plurality of adjacent target portions to which the circuit pattern is transferred successively by the lithographic projection apparatus, one target portion at a time. In one type of lithographic projection apparatuses, the circuit pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device are transferred to one target portion progressively. Since, in general, the lithographic projection apparatus will have a magnification factor M (generally <1), the speed F at which the substrate is moved will be a factor M times that at which the projection beam scans the patterning device. More information with regard to lithographic devices as described herein can be gleaned, for example, from U.S. Pat. No. 6,046,792, incorporated herein by reference.

Prior to transferring the circuit pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

As noted, lithography is a central step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

As semiconductor manufacturing processes continue to advance, the dimensions of functional elements have continually been reduced while the number of functional elements, such as transistors, per device has been steadily increasing over decades, following a trend commonly referred to as “Moore's law”. At the current state of technology, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k₁ lithography, according to the resolution formula CD=k₁×λ/NA, where λ is the wavelength of radiation employed (currently in most cases 248 nm or 193 nm), NA is the numerical aperture of projection optics in the lithographic projection apparatus, CD is the “critical dimension”—generally the smallest feature size printed—and k₁ is an empirical resolution factor. In general, the smaller k₁ the more difficult it becomes to reproduce a pattern on the substrate that resembles the shape and dimensions planned by a circuit designer in order to achieve particular electrical functionality and performance. To overcome these difficulties, sophisticated fine-tuning steps are applied to the lithographic projection apparatus and/or design layout. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### BRIEF SUMMARY

In some embodiments, there is provided a non-transitory computer readable medium having instructions that, when executed by a computer, cause the computer to execute a method for determining mask rule check violation associated with mask features. The method includes: placing a detector at a location on an edge of a mask feature, wherein the detector is two-dimensional (2D) geometrical structure; varying a size of the detector until the detector is in contact with a specified point, the specified point being on the edge of the mask feature or on an edge of another mask feature; determining a local feature dimension based on the size of the detector that causes the contact with the specified point; and determining a mask rule check (MRC) violation based on the local feature dimension.

In some embodiments, there is provided a non-transitory computer-readable medium having instructions that, when executed by a computer, cause the computer to execute a method for updating a mask design to reduce mask rule check violation associated with mask features. The method includes: obtaining a local feature dimension associated with a mask feature of a mask design; determining an MRC violation of the mask feature based on the local feature dimension; and adjusting, based on the local feature dimension, the mask feature to satisfy the MRC.

In some embodiments, there is provided a method for determining mask rule check violation associated with mask features. The method includes: placing a detector at a location on an edge of a mask feature, wherein the detector is two-dimensional (2D) geometrical structure; varying a size of the detector until the detector is in contact with a specified point, the specified point being on the edge of the mask feature or on an edge of another mask feature; determining a local feature dimension based on the size of the detector that causes the contact with the specified point; and determining a mask rule check (MRC) violation based on the local feature dimension.

In some embodiments, there is provided an apparatus for determining mask rule check violation associated with mask features. The apparatus includes: a memory storing a set of instructions; and a processor configured to execute the set of instructions to cause the apparatus to perform a method of: placing a detector at a location on an edge of a mask feature, wherein the detector is two-dimensional (2D) geometrical structure; varying a size of the detector until the detector is in contact with a specified point, the specified point being on the edge of the mask feature or on an edge of another mask feature; determining a local feature dimension based on the size of the detector that causes the contact with the specified point; and determining a mask rule check (MRC) violation based on the local feature dimension.

### BRIEF DESCRIPTION OF THE DRAWINGS

FIG. 1 is a block diagram of various subsystems of a lithography system, consistent with various embodiments.

FIG. 2 shows a flow for a lithographic process or patterning simulation method, consistent with various embodiments.

FIG. 3 is a block diagram of a system for improving a mask design based on a local feature dimension (LFD) of a mask feature, consistent with various embodiments.

FIG. 4 is a flow diagram of a method for performing a mask rule check (MRC), consistent with various embodiments.

FIG. 5A and FIG. 5B illustrate determination of an LFD of a mask feature, consistent with various embodiments.

FIG. 6A and FIG. 6B illustrate determination of an LFD of a mask feature, consistent with various embodiments.

FIG. 7 illustrates detection of an MRC violation of a mask feature based on an LFD, consistent with various embodiments.

FIG. 8A illustrates determination of a cost function based on the LFD of a mask feature, consistent with various embodiments.

FIG. 8B shows a graph depicting an example form of the kernel function, consistent with various embodiments.

FIG. 8C illustrates determination of a gradient to the cost function, consistent with various embodiments.

FIG. 9 is a flow diagram of a method for optimizing a mask design based on an LFD of a mask feature, consistent with various embodiments.

FIG. 10 is a flow diagram illustrating aspects of an example methodology of joint optimization/co-optimization, consistent with various embodiments.

FIG. 11 shows an embodiment of a further optimization method, consistent with various embodiments.

FIG. 12A, FIG. 12B and FIG. 13 show example flowcharts of various optimization processes, consistent with various embodiments.

FIG. 14 is a block diagram of an example computer system, according to an embodiment of the present disclosure.

### DETAILED DESCRIPTION

In lithography, to print a pattern on a substrate, the pattern (also often referred to as “design layout” or “design”) of a patterning device (e.g., a mask) is projected onto a layer of resist provided on a substrate (e.g., a wafer). The pattern may be projected onto one or more dies of the substrate. In some embodiments, the design layout or portions of the design layout are used for designing the mask to be employed in the semiconductor manufacturing. Generating a mask design includes determining mask features based on mask optimization simulations and checking whether the mask features satisfy a mask rule check (MRC). Conventional MRC violation detection processes may detect MRC violations of the mask features using detectors (e.g., circular, elliptical, or other shaped structures) that are glided along an edge of a mask feature to identify an MRC violation. The detectors may have fixed sizes during detection as defined according to MRC constraints such as minimum width or minimum curvature. Conventional techniques may have some drawbacks. For example, conventional MRC violation detection processes may not quantify the MRC violation. That is, the processes May not indicate the extent of an MRC violation in a measurable manner (e.g., expressed in a unit such as nanometer (nm)). Further, conventional MRC violation detection processes may detect an MRC violation based on a size of a mask feature being lesser than a minimum feature size, but may not detect an MRC violation based on the mask feature size being greater than a maximum feature size, which can be undesirable in some applications or scenarios.

Disclosed herein is a mechanism for improving detection of MRC violations related to mask designs, for example, having curvilinear mask features. The present disclosure provides detectors (e.g., a two-dimensional (2D) geometrical structure) that are not only configured to determine MRC violations for mask features having a size exceeding a specified size (e.g., maximum feature size specified in MRC) but also determine an extent of the MRC violation (e.g., in nm). For example, a detector is placed on an edge of a mask feature at a specified location and the size of the detector is varied until the detector is in contact with another location (e.g., one or more locations on the edge) of the mask feature or another mask feature (e.g., adjacent mask feature). The size of the detector when the detector is in contact with the other location is representative of a local feature dimension (LFD) of a portion of the mask feature at the location where the detector is placed. In some embodiments, the LFD is indicative of a size of the portion of the mask feature (e.g., between two specific locations on an edge of the mask feature) or a distance between two mask features. In this manner, the LFD of the mask feature may be determined based on the size of the detector (e.g., as a function of the radius of a circular detector). The embodiments may detect an MRC violation when the LFD is out of a specified LFD range (e.g., LFD is lesser than a minimum LFD or greater than a maximum LFD). In some embodiments, the extent of the MRC violation is determined as a difference between the actual LFD and the minimum or maximum LFD. The measured LFD may also be used in adjusting the mask design to minimize or eliminate MRC violations. For example, a cost function that is indicative of a penalty associated with a mask feature that violates the MRC may be determined as a function of the LFD. The mask feature may be updated (e.g., a size or shape of the mask feature) until the cost function is minimized. Thus, mask designs may be improved based on information related to LFD determined using the detectors. This may in turn improve the semiconductor manufacturing process that employs a mask designed based on information related to MRC violations, according to the present disclosure.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g., with a wavelength of 365, 248, 193, 157 or 126 nm) and EUV (extreme ultra-violet radiation, e.g., having a wavelength in the range of about 5-100 nm).

The term “optimizing” and “optimization” as used herein refers to or means adjusting a lithographic projection apparatus, a lithographic process, etc. such that results and/or processes of lithography have more desirable characteristics, such as higher accuracy of projection of a design layout on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Further, the lithographic projection apparatus may be of a type having two or more tables (e.g., two or more substrate table, a substrate table and a measurement table, two or more patterning device tables, etc.). In such “multiple stage” devices a plurality of the multiple tables may be used in parallel, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above comprises, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit devices (such as gates, capacitors, etc.) or interconnect lines, so as to ensure that the circuit devices or lines do not interact with one another in an undesirable way. One or more of the design rule limitations may be referred to as “critical dimensions” (CD). A critical dimension of a circuit can be defined as the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

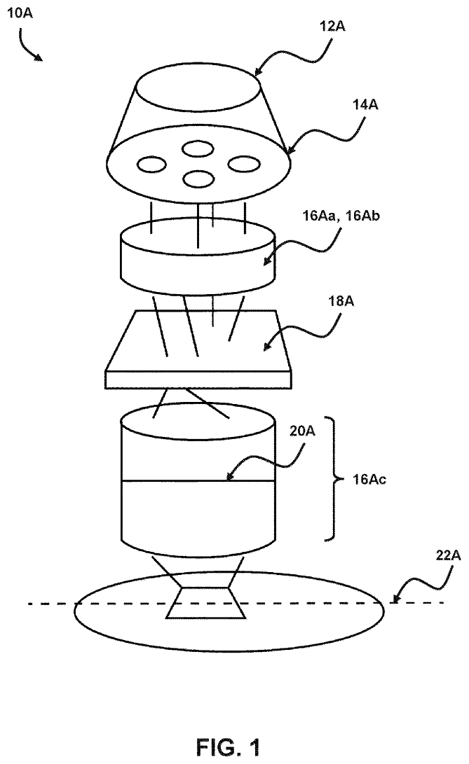

As a brief introduction, FIG. 1 illustrates an exemplary lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θₘₐₓ), n is the Index of Refraction of the media between the last element of projection optics and the substrate, and Θₘₐₓ is the largest angle of the beam exiting from the projection optics that can still impinge on the substrate plane 22A. The radiation from the radiation source 12A may not necessarily be at a single wavelength. Instead, the radiation may be at a range of different wavelengths. The range of different wavelengths may be characterized by a quantity called “imaging bandwidth,” “source bandwidth” or simply “bandwidth,” which are used interchangeably herein. A small bandwidth may reduce the chromatic aberration and associated focus errors of the downstream components, including the optics (e.g., optics 14A, 16Aa and 16Ab) in the source, the patterning device and the projection optics. However, that does not necessarily lead to a rule that the bandwidth should never be enlarged.

In an optimization process of a system, a figure of merit of the system can be represented as a cost function. The optimization process boils down to a process of finding a set of parameters (design variables) of the system that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (i.e., worst deviation). The term “evaluation points” herein should be interpreted broadly to include any characteristics of the system. The design variables of the system can be confined to finite ranges and/or be interdependent due to practicalities of implementations of the system. In the case of a lithographic projection apparatus, the constraints are often associated with physical properties and characteristics of the hardware such as tunable ranges, and/or patterning device manufacturability design rules, and the evaluation points can include physical points on a resist image on a substrate, as well as non-physical characteristics such as dose and focus.

In a lithographic projection apparatus, a source provides illumination (i.e., radiation) to a patterning device and projection optics direct and shape the illumination, via the patterning device, onto a substrate. The term “projection optics” is broadly defined here to include any optical component that may alter the wavefront of the radiation beam. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related only to properties of the resist layer (e.g., effects of chemical processes which occur during exposure, PEB and development). Optical properties of the lithographic projection apparatus (e.g., properties of the source, the patterning device and the projection optics) dictate the aerial image. Since the patterning device used in the lithographic projection apparatus can be changed, it is desirable to separate the optical properties of the patterning device from the optical properties of the rest of the lithographic projection apparatus including at least the source and the projection optics.

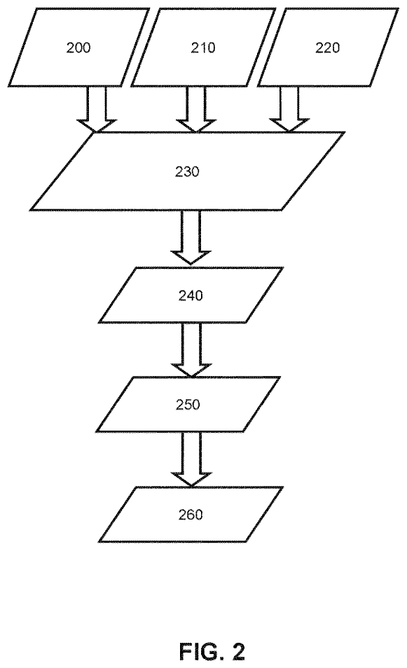

An exemplary flow chart for modelling and/or simulating parts of a patterning process is illustrated in FIG. 2. As will be appreciated, the models may represent a different patterning process and need not comprise all the models described below. A source model 200 represents optical characteristics (including radiation intensity distribution, bandwidth and/or phase distribution) of the illumination of a patterning device. The source model 200 can represent the optical characteristics of the illumination that include, but not limited to, numerical aperture settings, illumination sigma (σ) settings as well as any particular illumination shape (e.g., off-axis radiation shape such as annular, quadrupole, dipole, etc.), where σ (or sigma) is outer radial extent of the illuminator.

A projection optics model 210 represents optical characteristics (including changes to the radiation intensity distribution and/or the phase distribution caused by the projection optics) of the projection optics. The projection optics model 210 can represent the optical characteristics of the projection optics, including aberration, distortion, one or more refractive indexes, one or more physical sizes, one or more physical dimensions, etc.

The patterning device/design layout model module 220 captures how the design features are laid out in the pattern of the patterning device and may include a representation of detailed physical properties of the patterning device, as described, for example, in U.S. Pat. No. 7,587,704, which is incorporated by reference in its entirety. In an embodiment, the patterning device/design layout model module 220 represents optical characteristics (including changes to the radiation intensity distribution and/or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout, and will be provided in a standardized digital file format such as GDSII or OASIS.

An aerial image 230 can be simulated from the source model 200, the projection optics model 210 and the patterning device/design layout model module 220. An aerial image (AI) is the radiation intensity distribution at substrate level. Optical properties of the lithographic projection apparatus (e.g., properties of the illumination, the patterning device and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 250 can be simulated from the aerial image 230 using a resist model 240. The resist model can be used to calculate the resist image from the aerial image, an example of which can be found in U.S. Patent Application Publication No. US 2009-0157360, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In an embodiment, the optical properties of the resist layer, e.g., refractive index, film thickness, propagation and polarization effects—may be captured as part of the projection optics model 210.

So, in general, the connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In an embodiment, the resist image can be used an input to a post-pattern transfer process model module 260. The post-pattern transfer process model module 260 defines performance of one or more post-resist development processes (e.g., etch, development, etc.).

Simulation of the patterning process can, for example, predict contours, CDs, edge placement (e.g., edge placement error), etc. in the resist and/or etched image. Thus, the objective of the simulation is to accurately predict, for example, edge placement, and/or aerial image intensity slope, and/or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDSII or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process.

The following paragraphs describe determining a local feature dimension (LFD) of a mask feature, determining MRC violations based on the LFD and updating a mask design based on the LFD to eliminate the MRC violations.

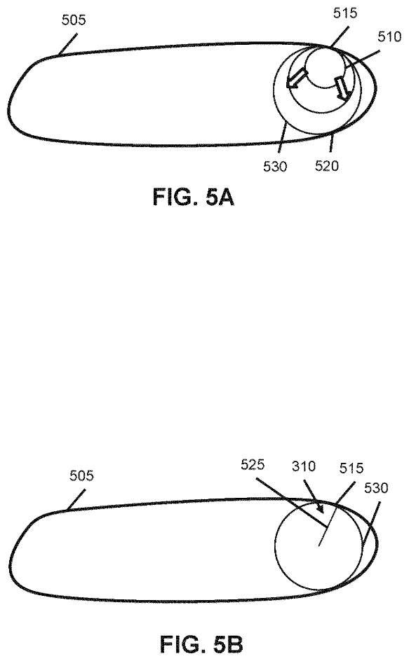

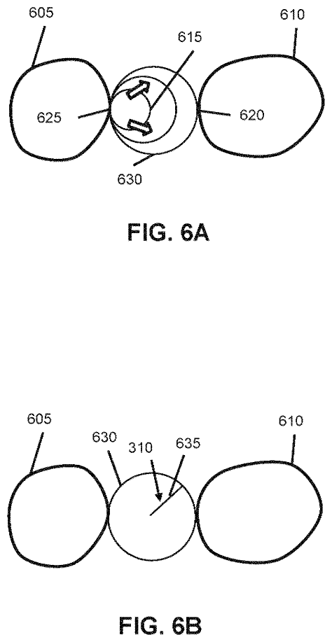

Typically, a mask may have thousands or even millions of mask features for which MRC may be performed. The MRC may be performed for each of the mask features. The mask features may be of any of various shapes, e.g., curvilinear mask feature. In some embodiments, a detector may be used to determine the MRC violations. A detector is a geometrical structure of any size or shape configured to help in detecting MRC violations of mask features of various shapes. For example, the detector may be a circular detector configured to perform MRC for curvilinear mask features having different curvature shapes and sizes (e.g., as illustrated in FIGS. 5A and 5B). In some embodiments, the detector can be configured to detect MRC violations related to spaces between two mask features (e.g., as illustrated in FIGS. 6A and 6B). These detectors may help in determining the MRC violations based on the LFD as described below.

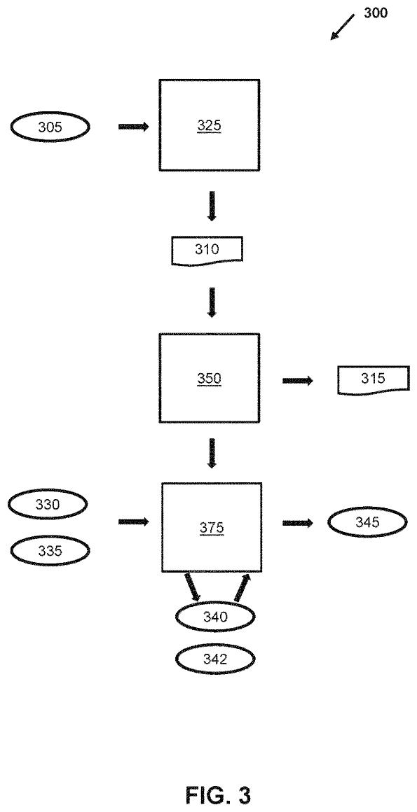

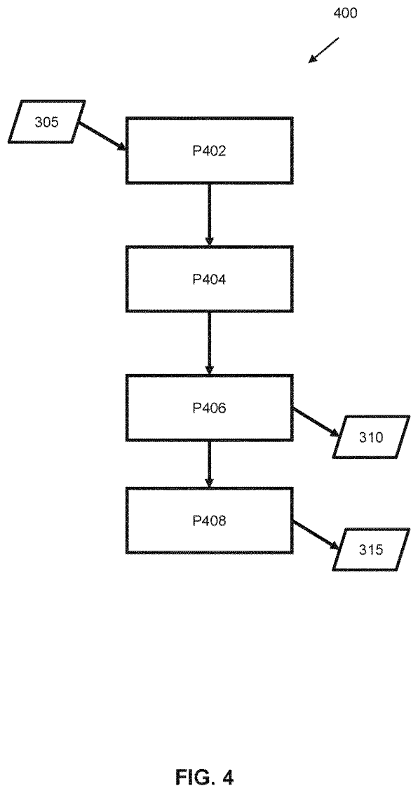

FIG. 3 is a block diagram of a system 300 for improving a mask design based on an LFD of mask feature, consistent with various embodiments. FIG. 4 is a flow diagram of a method 400 for performing an MRC, consistent with various embodiments. At process P402, an LFD component 325 obtains a mask design 305 having one or more mask features. In some embodiments, a mask design 305 is generated from a design layout by simulating a mask optimization process (e.g., SMO, OPC, etc.) to determine mask features (e.g., mask feature 505) for the mask design 305. The design layout may correspond to features to be printed on a semiconductor chip.

At process P404, the LFD component 325 places a detector on an edge or a contour of the mask feature. For example, the LFD component 325 places a detector 510 within the mask feature 505 at a first location 515 on the edge of the mask feature 505, as illustrated in FIG. 5A. The detector 510 may have certain geometric properties configured to facilitate MRC detection. In some embodiments, the detector 510 is configured to be a circle. In some embodiments, the mask feature 505 has a curvilinear shape. In some embodiments, the MRC 335 may include one or more geometric properties associated with the mask feature 505. The geometric properties may include a minimum critical dimension (CD) or LFD of the mask feature that can be manufactured, a minimum curvature of mask feature that can be manufactured, a minimum space between two features that can be manufactured, or a maximum CD or LFD of the mask feature that can be manufactured. In some embodiments, the LFD is a dimension or a size of the mask feature at a specified point on the edge of mask feature.

At process P406, the LFD component 325 may vary the size of the detector until the detector is in contact with another location of the mask feature. For example, the LFD component 325 may increase (or decrease) the size of the detector 510 until the detector 510 is in contact with another location, e.g., a second location 520 on the edge of the mask feature 505, at which point the detector 510 transforms to a detector 530. The LFD component 325 obtains an LFD 310 as a function of the size of the detector 530. For example, the LFD component 325 obtains the LFD 310 as a function of a radius 525 of the detector 530, as illustrated in FIG. 5B. The LFD 310 may be indicative of a size of a portion of the mask feature 505 at the first location 515. In some embodiments, the LFD 310 in FIGS. 5A and 5B may be referred to as an interior LFD as the LFD 310 is indicative of a dimension within the mask feature 505.

In some embodiments, the LFD component 325 may also determine an exterior LFD, which is indicative of a distance between two adjacent mask features, as illustrated in FIGS. 6A and 6B. For example, the LFD component 325 may place a detector 615 between a first mask feature 605 and a second mask feature 610. The detector 615 may be placed outside the first mask feature 605 at a first location 625 on the edge of the first mask feature 605. The LFD component 325 may vary the size of the detector 615 until the detector 615 is in contact with any location on the edge of the second mask feature 610, e.g., a second location 620, at which point the detector 615 transforms to a detector 630. The LFD component 325 may obtain an LFD 310 as a function of the size of the detector 630. For example, the LFD component 325 obtains the LFD 310 as a function of a radius 635 of the detector 630. The LFD 310 in FIG. 6B, which is also referred to as an exterior LFD, may be indicative of a distance between the first mask feature 605 and the second mask feature 610 at the first location 625.

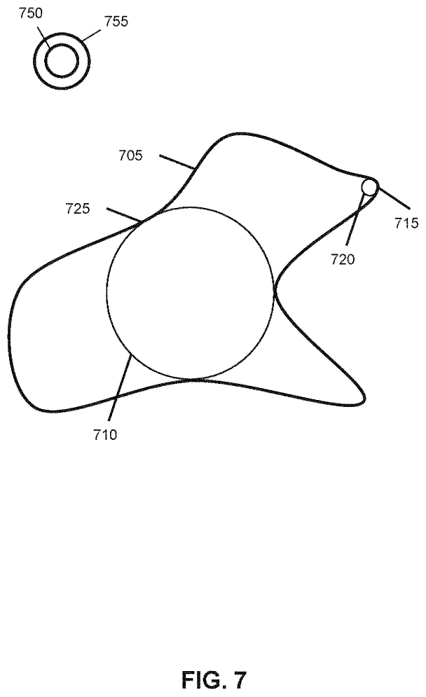

At process P408, an MRC violation component 350 detects an MRC violation based on the LFD of the mask features. In some embodiments, determining the occurrence of an MRC violation may involve comparing the LFD of a mask feature with LFD constraints specified in an MRC 335. In some embodiments, an MRC violation may occur when the geometric properties of the mask feature do not satisfy the constraints specified in the MRC. For example, the MRC violation component 350 may detect an MRC violation when the LFD 310 of the mask feature 505 is lesser than a minimum LFD or CD specified in the MRC 335. In another example, the MRC violation component 350 may detect an MRC violation when the LFD 310 of the mask feature 505 exceeds a maximum LFD or CD specified in the MRC 335. In yet another example, the MRC violation component 350 may detect an MRC violation when the LFD 310 associated with the first mask feature 605 is lesser than a minimum LFD or CD or greater than maximum LFD or CD specified in the MRC 335. FIG. 7 illustrates detection of an MRC violation of a mask feature based on an LFD, consistent with various embodiments. In some embodiments, an MRC 335 may specify constraints such as minimum LFD 750 and maximum LFD 755 within which the LFD of the mask feature should be. The MRC violation component 350 may detect an MRC violation of the mask feature 705 when the LFD determined using detector 720 at a first location 715 is lesser than the minimum LFD 750. In another example, the MRC violation component 350 may detect an MRC violation of the mask feature 705 when the LFD of the mask feature 705 determined using a detector 710 at a second location 725 exceeds the maximum LFD 755.

The MRC violation component 350 may also determine an extent of the MRC violation. In some embodiments, the extent of the MRC violation may be determined as a difference between the LFD of the mask feature corresponding to a location and the minimum or maximum LFD specified in the MRC 335 that is violated. For example, if the LFD for the mask feature 705 at the second location 725 is determined as 8 nm and the maximum LFD 755 specified in the MRC is 5 nm, the MRC violation component 350 may determine the extent of violation as 3 nm (8 nm-5 nm), which is a difference between the LFD of the mask feature 705 at the second location 725 and the maximum LFD 755.

The MRC violation component 350 may output MRC violation data 315, which includes MRC violation information for a mask feature, such as a location where the violation has occurred, a type of violation occurred (e.g., a minimum or maximum LFD violation), an LFD at the location, an extent of violation, etc. For example, with reference to FIG. 7, the MRC violation data 315 may include information such as location coordinates of the first location 715, minimum LFD violation as violation type, 3 nm as LFD at the first location 715, and 2 nm as MRC violation extent (considering minimum LFD 750 is 1 nm, for example) for the first MRC violation at the first location 715. Similarly, for the second MRC violation at the second location 725, the MRC violation data 315 may include information such as location coordinates of the second location 725, maximum LFD violation as the violation type, 8 nm as the LFD at the second location 725, and 3 nm (for example) as the extent of the MRC violations.

In some embodiments, the MRC violation data 315 (e.g., LFD information) may be used to improve a mask design by eliminating (e.g., or minimizing) MRC violations. A mask design component 375 may be configured to use a cost function 340 in adjusting a design of the mask feature (e.g., a shape or size) to eliminate the MRC violations. For example, the cost function 340 may be indicative of a penalty associated with a mask feature for violating the MRC 335. In some embodiments, the cost function 340 may be determined as a function of the LFD of the mask feature.

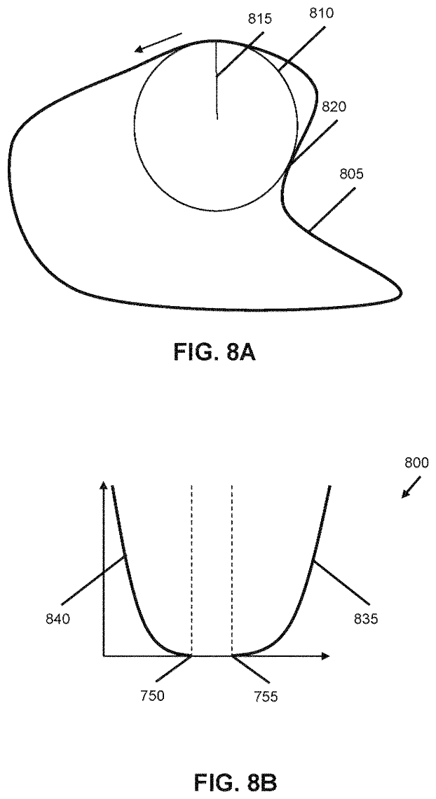

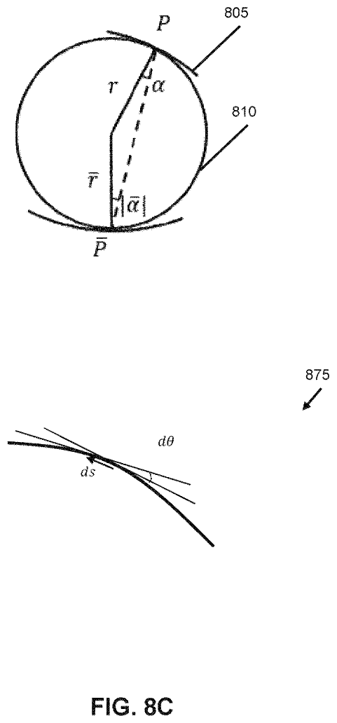

FIG. 8A illustrates determination of a cost function based on the LFD of a mask feature, consistent with various embodiments. As described above at least with reference FIG. 4, the LFD of a mask feature at a specified location may be a function of a radius of the detector placed on the edge at the specified location and its size adjusted such that it is in contact with one or more other locations of the mask feature. For example, the LFD of a portion of the mask feature 805 at a location 820 may be determined as a radius 815 of a detector 810 positioned at the location 820 such that the detector 810 is also in contact with one or more other points on the edge of the mask feature 805 and is still within the mask feature 805. That is, if radius 815 is depicted as r, then a kernel function may be depicted as ƒ(r). The kernel function may take any form. For example, kernel function may increase exponentially as the difference between the actual LFD and the minimum or maximum LFD increases. FIG. 8B shows a graph depicting an example form of the kernel function, consistent with various embodiments. Considering the x-axis as LFD values and y-axis as kernel function values in the graph 800, a first curve 840 indicates a kernel function value increasing exponentially as the LFD continues to decrease beyond the minimum LFD 750, and similarly, a second curve 835 indicates a kernel function value increasing exponentially as the LFD continues to increase beyond the maximum LFD 755. Accordingly, the kernel function, ƒ(r), may take any mathematical form that satisfies the above condition depicted in the graph 800.

In some embodiments, the cost function 340 may be determined as an integral of the kernel function along the contour, curve or edge of the mask feature 805. For example, the cost function 340, I, may be depicted as:

$$I = \int f ( r ) ds \qquad Eq . ( 1 A )$$

Where ds is length of a segment of the edge where the kernel function is determined.

In some embodiments, a gradient 342 to the cost function 340 may also be determined. The gradient 342, which is a derivative of the cost function 340, may be used with the cost function 340 to adjust or update a mask feature to eliminate the MRC violation. In some embodiments, given a mask feature, the cost function 340 may determine what may be the extent of the penalty, whereas the gradient 342 may determine how or to what extent the cost function 340 (e.g., penalty) varies when the mask feature is varied (e.g., shape or size of the mask feature is varied) in a particular way. In some embodiments, the gradient 342 may be determined based on at least one of the cost function, the LFD or a geometry of the mask feature, as described below.

FIG. 8C illustrates determination of a gradient to the cost function, consistent with various embodiments. The figure shows a portion of the mask feature 805 and the detector 810 used to determine the LFD of the mask feature 805 at the location P. A gradient density function, g(C), may be determined as follows:

$$g ( C ) = \frac{1 - {tan}^{2} α}{2} {f}^{′} ( r ) + \frac{1 + {tan}^{2} α}{2} \frac{1 - κ r}{1 - \overline{κ} r} {f}^{′} ( r ) - \frac{d}{ds} [ \frac{{f}^{′} ( r )}{1 - κ r} r \frac{dr}{ds} ] + κ f ( r ) \qquad Eq . ( 1 B )$$

Where κ is curvature and may be determined as dθ/ds as illustrated in an example 875; α is angle between the normal direction and the conjugate point (P̅) direction, ds is segment length r is radius or LFD as defined and ƒ′(r) is a derivative of the kernel function ƒ(r).

The gradient 342 may be determined as:

$$\frac{\partial I}{\partial {v}_{i}} = ∮ g ( C ) \frac{\partial δ l}{\partial {v}_{i}} ds \qquad Eq . ( 1 C )$$

where νᵢ is the i-th variable, and δl is the mask bias.

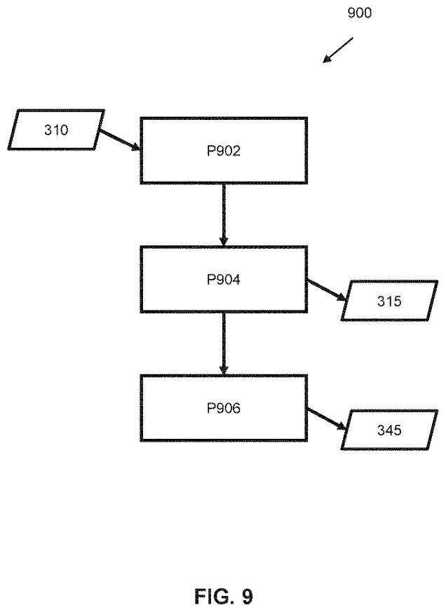

FIG. 9 is a flow diagram of a method 900 for optimizing a mask design based on an LFD of a mask feature, consistent with various embodiments. At process P902, the LFD component 325 may obtain an LFD of a mask feature. For example, the LFD component 325 may obtain the LFD 310 of a mask feature 505 as described at least with reference to processes P404 and P406 of the method 400 of FIG. 4. In some embodiments, the LFD is determined as a function of a size of the detector used to determine the LFD (e.g., as a function of a radius of a circular detector). For example, the LFD 310 may be determined as a function of the radius 525 of the detector 530 illustrated in FIG. 5B. In some embodiments, a mask design may be generated by simulating, using a design layout, a mask optimization process (e.g., SMO, OPC, etc.) to determine the mask features for the mask design. The design layout may correspond to features to be printed on a substrate.

At process P904, the MRC violation component 350 may determine an MRC violation of the mask feature based on the LFD. In some embodiments, an MRC violation may occur when the geometric properties of the mask feature do not satisfy the constraints specified in the MRC. For example, the MRC violation component 350 may detect an MRC violation when the LFD 310 of the mask feature 505 is lesser than a minimum LFD specified in the MRC or greater than a maximum LFD specified in the MRC, as described at least with reference to process P408 of the method 400. The MRC violation component 350 may output the MRC violation data 315, which includes MRC violation information for a mask feature, such as a location of mask feature where the violation has occurred, type of violation occurred (e.g., a minimum or maximum LFD violation), LFD at the location, extent of violation, etc.

At process P906, a mask design component 375 may optimize (e.g., adjust a mask feature) the mask feature based on the LFD to eliminate or reduce the MRC violation, thereby generating an adjusted, updated, or optimized mask design. For example, the mask design component 375 may obtain the cost function 340, which is indicative of a penalty associated with the mask feature for violating the MRC, and a gradient 342 of the cost function 340 based on the LFD associated with the mask feature 705 (e.g., as described at least with reference to FIGS. 8A-8C) and adjust or update the mask feature 705 (e.g., a shape, size or other geometry of the mask feature) to reduce the cost function 340 using the gradient 342. The mask design component 375 may then verify the updated mask design with the MRC 335 to determine if the updated mask feature 705 still violates the MRC 335 (e.g., if the LFD of the updated mask features violates the LFDs specified in the MRC 335). In some embodiments, the mask design component 375 may also verify imaging parameters of the updated mask design with imaging constraints 330 to determine if any of the imaging constraints are violated. Some of the imaging parameters may include image log slope (ILS), edge placement error (EPE), depth of focus (DOF), etc. The imaging parameters may be obtained in various ways, for example, from an aerial image or a resist image generated using one or more models described at least with reference to FIG. 2. The mask design component 375 may continue to update the mask feature 705 further if an MRC violation or image constraint violation is detected. The mask design component 375 may continue to update the mask feature 705 until a specified criterion is satisfied. For example, the specified criterion may include a predefined number of iterations of updating the mask feature. In another example, the specified criterion may include updating the mask feature 705 until the cost function 340 or the gradient 342 is minimized.

In some embodiments, adjusting, updating or optimizing the mask design may involve (a) simulating, using a design layout, a mask optimization process to determine the mask features for the mask design; (b) determining, via the detector, portions of the mask features that violate the MRC 335 (e.g., as discussed with respect to the method 400); and (c) responsive to violating the MRC 335, modifying the corresponding portions of the mask features to satisfy the MRC 335; and repeating steps (a)-(c).

In some embodiments, the above process may be performed for one or more mask features in the mask design that violate the MRC 335. After the optimization process concludes, the mask design component 375 may output the updated mask design 345 in which the MRC violations are eliminated or minimized.

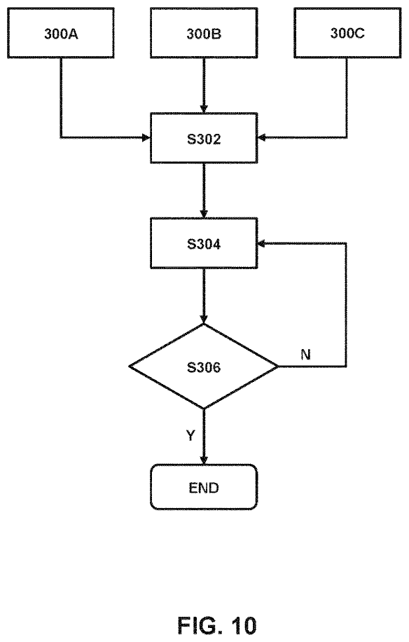

In some embodiments, the mask optimization process may involve a mask only optimization process, a source mask optimization (SMO) process, or an optical proximity correction (OPC) process. Example mask design process including OPC are discussed with respect to FIGS. 10-13. In some embodiments, the OPC process may be adapted to include the MRC violation check using detectors as discussed herein (e.g., FIGS. 5A-6B). In some embodiments, the check may be performed after a particular number of iterations, at an end of the OPC process, or other points in the simulation. After modifying the mask features that violate the MRC 335, the OPC process may be repeated to ensure cost functions associated with the OPC remain valid or within desired limits. In this way, the mask features obtained after the OPC simulation process will not only satisfy MRC, but also design specifications associated with the cost function.

Examples of mask optimization process including OPC process are further discussed in detail with respect to FIGS. 10-13. In some embodiments, the mask optimization process involves computing a cost function as a function of parameters associated with the lithographic process, and a mask. For example, the mask features may be represented as design variables, as discussed herein. These design variables will be affected due to changes based on the MRC violations detected by the detectors.

According to present disclosure, the combination and sub-combinations of disclosed elements constitute separate embodiments. For example, a first combination includes obtaining a detector, and determining MRC violations associated with mask features. The sub-combination may include the detector being a particular enclosed shape and size based on the mask feature, where MRC violations occur when a portion of the mask feature is inside the detector. In another sub-combination, the detector may be circular, or a non-circular shape. In another example, the combination includes determining a mask design based on a detector identified MRC violations. The detector having a non-circular shape that detects width, space and/or curvature violations.

In a lithographic process, as an example, a cost function may be expressed as

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) \qquad ( Eq . 1 )$$

wherein (z₁, z₂, . . . , z_{N}) are N design variables or values thereof. ƒₚ(z₁, z₂, . . . , z_{N}) can be a function of the design variables (z₁, z₂, . . . , z_{N}) such as a difference between an actual value and an intended value of a characteristic at an evaluation point for a set of values of the design variables of (z₁, z₂, . . . , z_{N}). wₚ is a weight constant associated with ƒₚ(z₁, z₂, . . . , z_{N}). An evaluation point or pattern more critical than others can be assigned a higher wₚ value. Patterns and/or evaluation points with larger number of occurrences may be assigned a higher wₚ value, too. Examples of the evaluation points can be any physical point or pattern on the substrate, any point on a virtual design layout, or resist image, or aerial image, or a combination thereof. CF(z₁, z₂, . . . , z_{N}) can be a function of the illumination source, a function of a variable that is a function of the illumination source or that affects the illumination source. Of course, CF(z₁, z₂, . . . , z_{N}) is not limited to the form in Eq. 1. CF(z₁, z₂, . . . , z_{N}) can be in any other suitable form.

The cost function may represent any one or more suitable characteristics of the lithographic projection apparatus, lithographic process or the substrate, for instance, focus, CD, image shift, image distortion, image rotation, stochastic variation, throughput, local CD variation, process window, or a combination thereof. In one embodiment, the design variables (z₁, z₂, . . . , z_{N}) comprise one or more selected from dose, global bias of the patterning device, and/or shape of illumination. In one embodiment, the design variables (z₁, z₂, . . . , z_{N}) comprise the bandwidth of the source. Since it is the resist image that often dictates the pattern on a substrate, the cost function may include a function that represents one or more characteristics of the resist image. For example, ƒₚ(z₁, z₂, . . . , z_{N}) of such an evaluation point can be simply a distance between a point in the resist image to an intended position of that point (i.e., edge placement error EPEₚ(z₁, z₂, . . . , z_{N})). The design variables can include any adjustable parameter such as an adjustable parameter of the source (e.g., the intensity, and shape), the patterning device, the projection optics, dose, focus, etc.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the evaluation points and the cost function. Such changes can be simulated from a model or actually measured.

The design variables may have constraints, which can be expressed as (z₁, z₂, . . . , z_{N})∈Z, where Z is a set of possible values of the design variables. One possible constraint on the design variables may be imposed by a desired throughput of the lithographic projection apparatus. Without such a constraint imposed by the desired throughput, the optimization may yield a set of values of the design variables that are unrealistic. For example, if the dose is a design variable, without such a constraint, the optimization may yield a dose value that makes the throughput economically impossible. However, the usefulness of constraints should not be interpreted as a necessity. For example, the throughput may be affected by the pupil fill ratio. For some illumination designs, a low pupil fill ratio may discard radiation, leading to lower throughput. Throughput may also be affected by the resist chemistry. Slower resist (e.g., a resist that requires higher amount of radiation to be properly exposed) leads to lower throughput. In an embodiment, the constraints on the design variables are such that the design variables cannot have values that change any geometrical characteristics of the patterning device—namely, the patterns on the patterning device will remain unchanged during the optimization.

The optimization process therefore is to find a set of values of the one or more design variables, under the constraints (z₁, z₂, . . . , z_{N})∈Z, that optimize the cost function, e.g., to find:

$$( {\tilde{z}}_{1} , {\tilde{z}}_{2} , … , {\tilde{z}}_{N} ) = arg {min}_{( {z}_{1} , {z}_{2} , … , {z}_{N} ) ∈ Z} CF ( {z}_{1} , {z}_{2} , … , {z}_{N} ) \qquad ( Eq . 2 )$$

A general method of optimizing, according to an embodiment, is illustrated in FIG. 10. This method comprises a step S302 of defining a multi-variable cost function of a plurality of design variables. The design variables may comprise any suitable combination selected from design variables representing one or more characteristics of the illumination (300A) (e.g., pupil fill ratio, namely percentage of radiation of the illumination that passes through a pupil or aperture), one or more characteristics of the projection optics (300B) and/or one or more characteristics of the design layout (300C). For example, the design variables may include design variables representing one or more characteristics of the illumination (300A) (e.g., being or including the bandwidth) and of the design layout (300C) (e.g., global bias) but not of one or more characteristics of the projection optics (300B), which leads to an illumination-patterning device (e.g., mask) optimization (“source-mask optimization” or SMO). Or, the design variables may include design variables representing one or more characteristics of the illumination (300A) (optionally polarization), of the projection optics (300B) and of the design layout (300C), which leads to an illumination-patterning device (e.g., mask)-projection system (e.g., lens) optimization (“source-mask-lens optimization” or SMLO). Or the design variables may include design variables representing one or more characteristics of the illumination (300A) (e.g., being or including the bandwidth), one or more non-geometrical characteristics of the patterning device, or one or more characteristics of the projection optics (300B), but not any geometrical characteristics of the patterning device. In step S304, the design variables are simultaneously adjusted so that the cost function is moved towards convergence. In an embodiment, not all design variables may be simultaneously adjusted. Each design variable may also be adjusted individually. In step S306, it is determined whether a predefined termination condition is satisfied. The predetermined termination condition may include various possibilities, e.g., one or more selected from: the cost function is minimized or maximized, as required by the numerical technique used, the value of the cost function is equal to a threshold value or crosses the threshold value, the value of the cost function reaches within a preset error limit, and/or a preset number of iterations is reached. If a condition in step S306 is satisfied, the method ends. If the one or more conditions in step S306 is not satisfied, the steps S304 and S306 are iteratively repeated until a desired result is obtained. The optimization does not necessarily lead to a single set of values for the one or more design variables because there may be a physical restraint, caused by a factor such as pupil fill factor, resist chemistry, throughput, etc. The optimization may provide multiple sets of values for the one or more design variables and associated performance characteristics (e.g., the throughput) and allows a user of the lithographic apparatus to pick one or more sets.

Different subsets of the design variables (e.g., one subset including characteristics of the illumination, one subset including characteristics of patterning device and one subset including characteristics of projection optics) can be optimized alternatively (referred to as Alternative Optimization) or optimized simultaneously (referred to as Simultaneous Optimization). So, two subsets of design variables being optimized “simultaneously” or “jointly” means that the design variables of the two subsets are allowed to change at the same time. Two subsets of design variables being optimized “alternatively” as used herein means that the design variables of the first subset but not the second subset are allowed to change in the first optimization and then the design variables of the second subset but not the first subset are allowed to change in the second optimization.

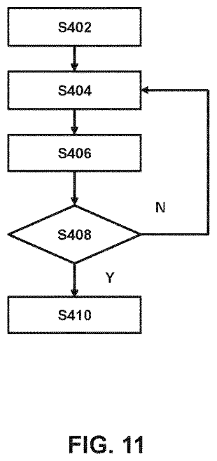

In FIG. 10, the optimization of all the design variables is executed simultaneously. Such a flow may be called simultaneous flow or co-optimization flow. Alternatively, the optimization of all the design variables is executed alternatively, as illustrated in FIG. 11. In this flow, in each step, some design variables are fixed while other design variables are optimized to optimize the cost function; then in the next step, a different set of variables are fixed while the others are optimized to minimize or maximize the cost function. These steps are executed alternatively until convergence or a certain terminating condition is met. As shown in the non-limiting example flowchart of FIG. 11, first, a design layout (step S402) is obtained, then a step of illumination optimization is executed in step S404, where the one or more design variables (e.g., the bandwidth) of the illumination are optimized (SO) to minimize or maximize the cost function while other design variables are fixed. Then in the next step S406, a projection optics optimization (LO) is performed, where the design variables of the projection optics are optimized to minimize or maximize the cost function while other design variables are fixed. These two steps are executed alternatively, until a certain terminating condition is met in step S408. One or more various termination conditions can be used, such as the value of the cost function becomes equal to a threshold value, the value of the cost function crosses the threshold value, the value of the cost function reaches within a preset error limit, a preset number of iterations is reached, etc. Note that SO-LO-Alternative-Optimization is used as an example for the alternative flow. As another example, a first illumination-patterning device co-optimization (SMO) or illumination-patterning device-projection optics co-optimization (SMLO) can be performed without allowing the bandwidth to change, followed by a second SO or illumination-projection optics co-optimization (SLO) allowing the bandwidth to change. Finally, the output of the optimization result is obtained in step S410, and the process stops.

The pattern selection algorithm, as discussed before, may be integrated with the simultaneous or alternative optimization. For example, when an alternative optimization is adopted, first a full-chip SO can be performed, one or more ‘hot spots’ and/or ‘warm spots’ are identified, then a LO is performed. In view of the present disclosure numerous permutations and combinations of sub-optimizations are possible in order to achieve the desired optimization results.

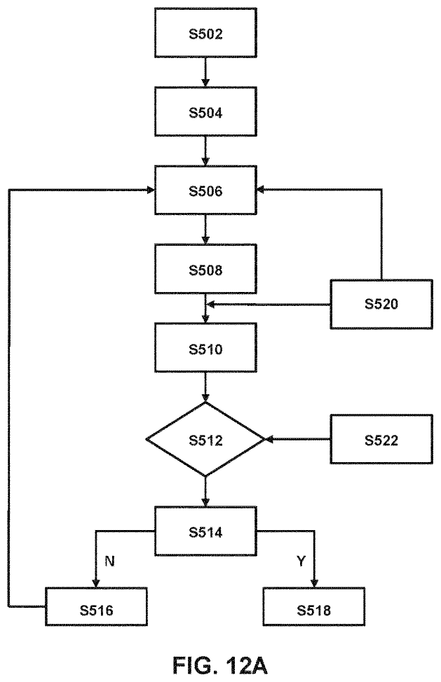

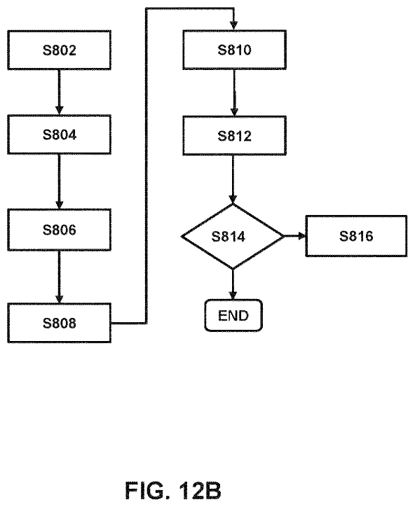

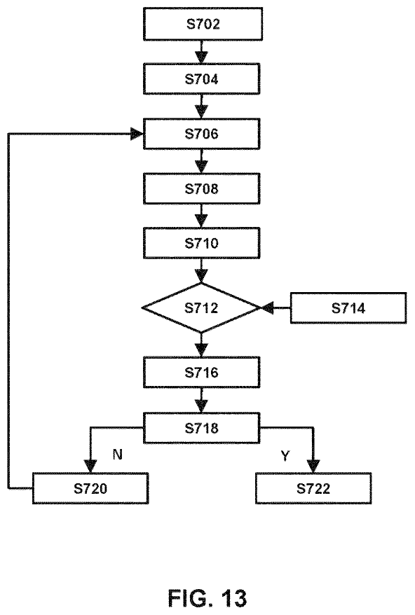

FIG. 12A shows one exemplary method of optimization, where a cost function is minimized or maximized. In step S502, initial values of one or more design variables are obtained, including one or more associated tuning ranges, if any. In step S504, the multi-variable cost function is set up. In step S506, the cost function is expanded within a small enough neighborhood around the starting point value of the one or more design variables for the first iterative step (i=0). In step S508, standard multi-variable optimization techniques are applied to the cost function. Note that the optimization problem can apply constraints, such as the one or more tuning ranges, during the optimization process in S508 or at a later stage in the optimization process. Step S520 indicates that each iteration is done for the one or more given test patterns (also known as “gauges”) for the identified evaluation points that have been selected to optimize the lithographic process. In step S510, a lithographic response is predicted. In step S512, the result of step S510 is compared with a desired or ideal lithographic response value obtained in step S522. If the termination condition is satisfied in step S514, i.e., the optimization generates a lithographic response value sufficiently close to the desired value, then the final value of the design variables is outputted in step S518. The output step may also include outputting one or more other functions using the final values of the design variables, such as outputting a wavefront aberration-adjusted map at the pupil plane (or other planes), an optimized illumination map, and/or optimized design layout etc. If the termination condition is not satisfied, then in step S516, the values of the one or more design variables is updated with the result of the i-th iteration, and the process goes back to step S506. The process of FIG. 12A is elaborated in detail below.

In an exemplary optimization process, no relationship between the design variables (z₁, z₂, . . . , z_{N}) and fₚ(z₁, z₂, . . . , z_{N}) is assumed or approximated, except that fₚ(z₁, z₂, . . . , z_{N}) is sufficiently smooth (e.g. first order derivatives

$$\frac{\partial {f}_{p} ( {z}_{1} , {z}_{2} , … , {z}_{N} )}{\partial {z}_{n}} ,$$

(n=1, 2, . . . N) exist), which is generally valid in a lithographic projection apparatus. An algorithm, such as the Gauss-Newton algorithm, the Levenberg-Marquardt algorithm, the Broyden-Fletcher-Goldfarb-Shanno algorithm, the gradient descent algorithm, the simulated annealing algorithm, the interior point algorithm, and the genetic algorithm, can be applied to find (\tilde{z}₁, \tilde{z}₂, . . . , \tilde{z}_{N}).

Here, the Gauss-Newton algorithm is used as an example. The Gauss-Newton algorithm is an iterative method applicable to a general non-linear multi-variable optimization problem. In the i-th iteration wherein the design variables (z₁, z₂, . . . , z_{N}) take values of (z₁ᵢ, z₂ᵢ, . . . , z_{Ni}), the Gauss-Newton algorithm linearizes ƒₚ(z₁, z₂, . . . , z_{N}) in the vicinity of (z₁ᵢ, z₂ᵢ, . . . , z_{Ni}), and then calculates values (z_{1 (i+1)}, z₂₍ᵢ₊₁₎, . . . , z_{N(i+1)}) in the vicinity of (z₁ᵢ, z₂ᵢ, . . . , z_{Ni}) that give a minimum of CF(z₁, z₂, . . . , z_{N}). The design variables (z₁, z₂, . . . , z_{N}) take the values of (z₁₍ᵢ₊₁₎, z₂₍ᵢ₊₁₎, . . . , z_{N(i+1)}) in the (i+1)-th iteration. This iteration continues until convergence (i.e., CF(z₁, z₂, . . . , z_{N}) does not reduce any further) or a preset number of iterations is reached.

Specifically, in the i-th iteration, in the vicinity of (z₁ᵢ, z₂ᵢ, . . . , z_{Ni}),

$${f}_{p} ( {z}_{1} , {z}_{2} , … , {z}_{N} ) \approx {f}_{p} ( {z}_{1 i} , {z}_{2 i} , … , {z}_{Ni} ) + {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} ( {z}_{n} = {z}_{ni} ) \qquad ( Eq . 3 )$$

Under the approximation of Eq. 3, the cost function becomes:

$$CF ( {z}_{1} , {z}_{2} , … , {z}_{N} ) = {\sum }_{p = 1}^{P} {w}_{p} {f}_{p}^{2} ( {z}_{1} , {z}_{2} , … , {z}_{N} ) = {\sum }_{p = 1}^{P} {{w}_{p} ( {f}_{p} ( {z}_{1 i} , {z}_{2 i} , … , {z}_{Ni} ) + {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} ( {z}_{n} = {z}_{ni} ) )}^{2} \qquad ( Eq . 4 )$$

which is a quadratic function of the design variables (z₁, z₂, . . . , z_{N}). Every term is constant except the design variables (z₁, z₂, . . . , z_{N}).

If the design variables (z₁, z₂, . . . , z_{N}) are not under any constraints, (z₁₍ᵢ₊₁₎, z₂₍ᵢ₊₁₎, . . . , z_{N(i+1)}) can be derived by solving N linear equations:

$$\frac{\partial CF ( {z}_{1} , {z}_{2} , … , {z}_{N} )}{\partial {z}_{n}} = 0 ,$$

wherein n=1, 2, . . . , N.

If the design variables (z₁, z₂, . . . , z_{N}) are under constraints in the form of J inequalities (e.g. tuning ranges of (z₁, z₂, . . . , z_{N})) Σₙ₌₁^{N} Aₙⱼzₙ≤Bⱼ, for j=1, 2, . . . , J; and K equalities (e.g. interdependence between the design variables) Σₙ₌₁^{N}Cₙₖzₙ≤Dₖ, for k=1, 2, . . . , K, the optimization process becomes a classic quadratic programming problem, wherein Aₙⱼ, Bⱼ, Cₙₖ, Dₖ are constants. Additional constraints can be imposed for each iteration. For example, a “damping factor” Δ_{D}, can be introduced to limit the difference between (z₁₍ᵢ₊₁₎, z₂₍ᵢ₊₁₎, . . . , z_{N(i+1)}) and (z₁ᵢ, z₂ᵢ, . . . , z_{Ni}), so that the approximation of Eq. 3 holds. Such constraints can be expressed as zₙᵢ−Δ_{D}≤zₙ≤zₙᵢ+Δ_{D}. (z₁₍ᵢ₊₁₎, z₂₍ᵢ₊₁₎, . . . , z_{N(i+1)}) can be derived using, for example, methods described in Numerical Optimization (2^{nd} ed.) by Jorge Nocedal and Stephen J. Wright (Berlin New York: Vandenberghe. Cambridge University Press).

Instead of minimizing the RMS of ƒₚ(z₁, z₂, . . . , z_{N}), the optimization process can minimize magnitude of the largest deviation (the worst defect) among the evaluation points to their intended values. In this approach, the cost function can alternatively be expressed as

$$CF ( {z}_{1} , {z}_{2} , … , {z}_{N} ) = {max}_{1 \leq p \leq P} \frac{{f}_{p} ( {z}_{1} , {z}_{2} , … , {z}_{N} )}{{CL}_{p}} \qquad ( Eq . 5 )$$

wherein CLₚ is the maximum allowed value for ƒₚ(z₁, z₂, . . . , z_{N}). This cost function represents the worst defect among the evaluation points. Optimization using this cost function minimizes magnitude of the worst defect. An iterative greedy algorithm can be used for this optimization.

The cost function of Eq. 5 can be approximated as:

$$CF ( {z}_{1} , {z}_{2} , … , {z}_{N} ) = {\sum }_{p = 1}^{P} {{w}_{p} ( \frac{{f}_{p} ( {z}_{1} , {z}_{2} , … , {z}_{N} )}{{CL}_{p}} )}^{q} \qquad ( Eq . 6 )$$

wherein q is an even positive integer such as at least 4, or at least 10. Eq. 6 mimics the behavior of Eq. 5, while allowing the optimization to be executed analytically and accelerated by using methods such as the deepest descent method, the conjugate gradient method, etc.

Minimizing the worst defect size can also be combined with linearizing of ƒₚ(z₁, z₂, . . . , z_{N}). Specifically, ƒₚ(z₁, z₂, . . . , z_{N}) is approximated as in Eq. 3. Then the constraints on worst defect size are written as inequalities E_{Lp}≤ƒₚ(z₁, z₂, . . . , z_{N})≤E_{Up}, wherein E_{Lp} and E_{Up}, are two constants specifying the minimum and maximum allowed deviation for the ƒₚ(z₁, z₂, . . . , z_{N}). Plugging Eq. 3 in, these constraints are transformed to, for p=1, . . . . P,

$${\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} {z}_{n} \leq {E}_{Up} + {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} {z}_{ni} - {f}_{p} ( {z}_{1 i} , {z}_{2 i} , … , {z}_{Ni} ) \qquad ( Eq . 6 ’ )$$

$$and$$

$$- {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} {z}_{n} \leq - {E}_{Up} - {\sum }_{n = 1}^{N} \frac{\partial {f}_{p} ( {z}_{1} , {z}_{2} , … , {z}_{N} )}{\partial {z}_{n}} {\vert}_{{z}_{1} = {z}_{1 i} , {z}_{2} = {z}_{2 i} , … {z}_{N} = {z}_{Ni}} {z}_{ni} + {f}_{p} ( {z}_{1 i} , {z}_{2 i} , … , {z}_{Ni} ) \qquad ( Eq . 6 ” )$$

Since Eq. 3 is generally valid only in the vicinity of (z₁, z₂, . . . , z_{N}), in case the desired constraints E_{Lp}≤ƒₚ(z₁, z₂, . . . , z_{N})≤E_{Up} cannot be achieved in such vicinity, which can be determined by any conflict among the inequalities, the constants E_{Lp} and E_{Up} can be relaxed until the constraints are achievable. This optimization process minimizes the worst defect size in the vicinity of (z₁, z₂, . . . , z_{N}), i. Then each step reduces the worst defect size gradually, and each step is executed iteratively until certain terminating conditions are met. This will lead to optimal reduction of the worst defect size.

Another way to minimize the worst defect is to adjust the weight wₚ in each iteration. For example, after the i-th iteration, if the r-th evaluation point is the worst defect, wᵣ can be increased in the (i+1)-th iteration so that the reduction of that evaluation point's defect size is given higher priority.

In addition, the cost functions in Eq. 4 and Eq. 5 can be modified by introducing a Lagrange multiplier to achieve compromise between the optimization on RMS of the defect size and the optimization on the worst defect size, i.e.,

$$CF ( {z}_{1} , {z}_{2} , … , {z}_{N} ) = ( 1 - λ ) {\sum }_{p = 1}^{P} {w}_{p} {f}_{p}^{2} ( {z}_{1} , {z}_{2} , … , {z}_{N} ) + λ {max}_{1 \leq p \leq P} \frac{{f}_{p} ( {z}_{1} , {z}_{2} , … , {z}_{N} )}{{CL}_{p}} \qquad ( Eq . 6 ’ ’ ’ )$$

where λ is a preset constant that specifies the trade-off between the optimization on RMS of the defect size and the optimization on the worst defect size. In particular, if λ=0, then this becomes Eq. 4 and the RMS of the defect size is only minimized; while if λ=1, then this becomes Eq. 5 and the worst defect size is only minimized; if 0<λ<1, then both are taken into consideration in the optimization. Such optimization can be solved using multiple methods. For example, the weighting in each iteration may be adjusted, similar to the one described previously. Alternatively, similar to minimizing the worst defect size from inequalities, the inequalities of Eq. 6′ and 6″ can be viewed as constraints of the design variables during solution of the quadratic programming problem. Then, the bounds on the worst defect size can be relaxed incrementally or increase the weight for the worst defect size incrementally, compute the cost function value for every achievable worst defect size, and choose the design variable values that minimize the total cost function as the initial point for the next step. By doing this iteratively, the minimization of this new cost function can be achieved.

Optimizing a lithographic projection apparatus can expand the process window. A larger process window provides more flexibility in process design and chip design. The process window can be defined as, for example, a set of focus, dose, aberration, laser bandwidth (e.g., E95 or (λmin to λmax) and fare specific to intensity values for which the resist image is within a certain limit of the design target of the resist image. Note that all the methods discussed here may also be extended to a generalized process window definition that can be established by different or additional base parameters than exposure dose and defocus. These may include, but are not limited to, optical settings such as NA, sigma, aberration, polarization, or an optical constant of the resist layer. For example, as described earlier, if the process window (PW) also comprises different patterning device pattern bias (mask bias), then the optimization includes the minimization of Mask Error Enhancement Factor (MEEF), which is defined as the ratio between the substrate edge placement error (EPE) and the induced patterning device pattern edge bias. The process window defined on focus and dose values only serve as an example in this disclosure.

A method of maximizing a process window using, for example, dose and focus as its parameters, according to an embodiment, is described below. In a first step, starting from a known condition (ƒ₀, ε₀) in the process window, wherein ƒ₀ is a nominal focus and ε₀ is a nominal dose, minimizing one of the cost functions below in the vicinity (ƒ₀+Δƒ, ε₀±ε):

$$CF ( {z}_{1} , {z}_{2} , … , {z}_{N ,} {f}_{0} , {ε}_{0} ) = {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert \qquad ( Eq . 7 )$$

$$or$$

$$CF ( {z}_{1} , {z}_{2} , … , {z}_{N ,} {f}_{0} , {ε}_{0} ) = {\sum }_{( f , ε ) = ( {f}_{0} \pm Δ f , {ε}_{0} \pm ε )} {\sum }_{p} {w}_{p} {f}_{p}^{2} ( {z}_{1} , {z}_{2} , … , {z}_{N} , f , ε ) \qquad ( Eq . 7 ’ )$$

$$or$$

$$CF ( {z}_{1} , {z}_{2} , … , {z}_{N ,} {f}_{0} , {ε}_{0} ) = ( 1 - λ ) {\sum }_{( f , ε ) = ( {f}_{0} \pm Δ f , {ε}_{0} \pm ε )} {\sum }_{p} {w}_{p} {f}_{p}^{2} ( {z}_{1} , {z}_{2} , … , {z}_{N} , f , ε ) + λ {max}_{( f , ε ) = ( {f}_{0} \pm Δ f , {ε}_{0} \pm ε )} {max}_{p} \vert {f}_{p} ( {z}_{1} , {z}_{2} , … , {z}_{N} , f , ε ) \vert \qquad ( Eq . 7 ” )$$

If the nominal focus ƒ₀ and nominal dose ε₀ are allowed to shift, they can be optimized jointly with the design variables (z₁, z₂, . . . , z_{N}). In the next step, (ƒ₀+Δƒ, ε₀±ε) is accepted as part of the process window, if a set of values of (z₁, z₂, . . . , z_{N}, ƒ, ε) can be found such that the cost function is within a preset limit.

If the focus and dose are not allowed to shift, the design variables (z₁, z₂, . . . , z_{N}) are optimized with the focus and dose fixed at the nominal focus ƒ₀ and nominal dose ε₀. In an alternative embodiment, (ƒ₀+Δƒ, ε₀+ε) is accepted as part of the process window, if a set of values of (z₁, z₂, . . . , z_{N}) can be found such that the cost function is within a preset limit.

The methods described earlier in this disclosure can be used to minimize the respective cost functions of Eqs. 7, 7′, or 7″. If the design variables represent one or more characteristics of the projection optics, such as the Zernike coefficients, then minimizing the cost functions of Eqs. 7, 7′, or 7″ leads to process window maximization based on projection optics optimization, i.e., LO. If the design variables represent one or more characteristics of the illumination and patterning device in addition to those of the projection optics, then minimizing the cost function of Eqs. 7, 7′, or 7″ leads to process window maximizing based on SMLO, as illustrated in FIG. 10. If the design variables represented one or more characteristics of the source and patterning device, then minimizing the cost functions of Eqs. 7, 7′, or 7″ leads to process window maximization based on SMO. The cost functions of Eqs. 7, 7′, or 7″ can also include at least one ƒₚ(z₁, z₂, . . . , z_{N}) such as described herein, that is a function of the bandwidth.

FIG. 13 shows one specific example of how a simultaneous SMLO process can use a gradient based optimization (e.g., quasi newton, or Gauss Newton Algorithm). In step S702, starting values of one or more design variables are identified. A tuning range for each variable may also be identified. In step S704, the cost function is defined using the one or more design variables. In step S706, the cost function is expanded around the starting values for all evaluation points in the design layout. In step S708, a suitable optimization technique is applied to minimize or maximize the cost function. In optional step S710, a full-chip simulation is executed to cover all critical patterns in a full-chip design layout. A desired lithographic response metric (such as CD, EPE, or EPE and PPE) is obtained in step S714, and compared with predicted values of those quantities in step S712. In step S716, a process window is determined. Steps S718, S720, and S722 are similar to corresponding steps S514, S516 and S518, as described with respect to FIG. 12A. As mentioned before, the final output may be, for example, a wavefront aberration map in the pupil plane, optimized to produce the desired imaging performance. The final output may be, for example, an optimized illumination map and/or an optimized design layout.

FIG. 12B shows an exemplary method to optimize the cost function where the design variables (z₁, z₂, . . . , z_{N}) include design variables that may only assume discrete values.

The method starts by defining the pixel groups of the illumination and the patterning device tiles of the patterning device (step S802). Generally, a pixel group or a patterning device tile may also be referred to as a division of a lithographic process component. In one exemplary approach, the illumination is divided into “117” pixel groups, and 94 patterning device tiles are defined for the patterning device, substantially as described above, resulting in a total of 211 divisions.

In step S804, a lithographic model is selected as the basis for lithographic simulation. A lithographic simulation produces results that are used in calculations of one or more lithographic metrics, or responses. A particular lithographic metric is defined to be the performance metric that is to be optimized (step S806). In step S808, the initial (pre-optimization) conditions for the illumination and the patterning device are set up. Initial conditions include initial states for the pixel groups of the illumination and the patterning device tiles of the patterning device such that references may be made to an initial illumination shape and an initial patterning device pattern. Initial conditions may also include patterning device pattern bias (sometimes referred to as mask bias), NA, and/or focus ramp range. Although steps S802, S804, S806, and S808 are depicted as sequential steps, it will be appreciated that in other embodiments, these steps may be performed in other sequences.

In step S810, the pixel groups and patterning device tiles are ranked. Pixel groups and patterning device tiles may be interleaved in the ranking. Various ways of ranking may be employed, including: sequentially (e.g., from pixel group “1” to pixel group “117” and from patterning device tile “1” to patterning device tile 94), randomly, according to the physical locations of the pixel groups and patterning device tiles (e.g., ranking pixel groups closer to the center of the illumination higher), and/or according to how an alteration of the pixel group or patterning device tile affects the performance metric.

Once the pixel groups and patterning device tiles are ranked, the illumination and patterning device are adjusted to improve the performance metric (step S812). In step S812, each of the pixel groups and patterning device tiles are analyzed, in order of ranking, to determine whether an alteration of the pixel group or patterning device tile will result in an improved performance metric. If it is determined that the performance metric will be improved, then the pixel group or patterning device tile is accordingly altered, and the resulting improved performance metric and modified illumination shape or modified patterning device pattern form the baseline for comparison for subsequent analyses of lower-ranked pixel groups and patterning device tiles. In other words, alterations that improve the performance metric are retained. As alterations to the states of pixel groups and patterning device tiles are made and retained, the initial illumination shape and initial patterning device pattern changes accordingly, so that a modified illumination shape and a modified patterning device pattern result from the optimization process in step S812.

In other approaches, patterning device polygon shape adjustments and pairwise polling of pixel groups and/or patterning device tiles are also performed within the optimization process of S812.

In an embodiment, the interleaved simultaneous optimization procedure may include altering a pixel group of the illumination and if an improvement of the performance metric is found, the dose or intensity is stepped up and/or down to look for further improvement. In a further embodiment, the stepping up and/or down of the dose or intensity may be replaced by a bias change of the patterning device pattern to look for further improvement in the simultaneous optimization procedure.

In step S814, a determination is made as to whether the performance metric has converged.

The performance metric may be considered to have converged, for example, if little or no improvement to the performance metric has been witnessed in the last several iterations of steps S810 and S812. If the performance metric has not converged, then the steps of S810 and S812 are repeated in the next iteration, where the modified illumination shape and modified patterning device from the current iteration are used as the initial illumination shape and initial patterning device for the next iteration (step S816).

The optimization methods described above may be used to increase the throughput of the lithographic projection apparatus. For example, the cost function may include a ƒₚ(z₁, z₂, . . . , z_{N}) that is a function of the exposure time. In an embodiment, optimization of such a cost function is constrained or influenced by a measure of the bandwidth or other metric.

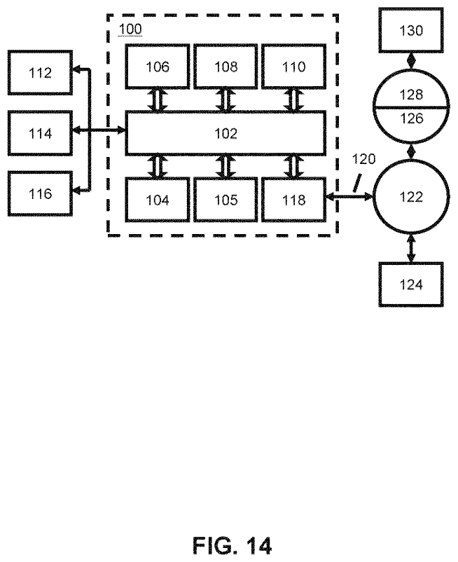

FIG. 14 is a block diagram that illustrates a computer system 100 which can assist in implementing the optimization methods and flows disclosed herein. The computer system 100 may be used to implement any of the entities, components, modules, or services depicted in the examples of the figures (and any other entities, components, modules, or services described in this specification). The computer system 100 may be programmed to execute computer program instructions to perform functions, methods, flows, or services (e.g., of any of the entities, components, or modules) described herein. The computer system 100 may be programmed to execute computer program instructions by at least one of software, hardware, or firmware.

Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. Thus, the description herein is not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

Embodiments of the present disclosure can be further described by the following clauses.

1. A non-transitory computer-readable medium having instructions that, when executed by a computer, cause the computer to execute a method for determining mask rule check violation associated with mask features, the method comprising:
placing a detector at a location on an edge of a mask feature, wherein the detector is two-dimensional (2D) geometrical structure;
varying a size of the detector until the detector is in contact with a specified point, the specified point being on the edge of the mask feature or on an edge of another mask feature;
determining a local feature dimension based on the size of the detector that causes the contact with the specified point; and
determining a mask rule check (MRC) violation based on the local feature dimension.
   2. The computer-readable medium of clause 1, wherein the MRC violation comprises a violation of a maximum critical dimension (CD).
   3. The computer-readable medium of clause 2, wherein the violation of the maximum CD occurs when the local feature dimension exceeds the maximum CD.
   4. The computer-readable medium of clause 1, wherein the MRC violation comprises a violation of a minimum CD.
   5. The computer-readable medium of clause 4, wherein the violation of the minimum CD occurs when the local feature dimension is lesser than the minimum CD.
   6. The computer-readable medium of clause 1, wherein determining the MRC violation includes:
determining the MRC violation based on the local feature dimension at multiple locations on the edge of the mask feature.
   7. The computer-readable medium of clause 1 further comprising:
obtaining a kernel function of the local feature dimension; and
determining a cost function based on the kernel function, wherein the cost function is indicative of an extent of the MRC violation.
   8. The computer-readable medium of clause 7 further comprising:
obtaining a gradient of the cost function based on one or more of the cost function, the local feature dimension or a geometry of the mask feature.
   9. The computer-readable medium of clause 7 further comprising:
adjusting the mask feature based on the cost function and a gradient of the cost function to eliminate the MRC violation.
   10. The computer-readable medium of clause 6, wherein adjusting the mask feature is an iterative process in which each iteration includes:
(a) obtaining imaging properties of the mask feature;
(b) determining whether the imaging properties satisfy an imaging criterion;
(c) determining whether the mask feature satisfies MRC criterion;
(d) computing the cost function that is indicative of the MRC violation; and
(e) responsive to a determination that the imaging criterion or the MRC criterion is not satisfied, adjusting a geometry of the mask feature to reduce the cost function.
   11. The computer-readable medium of clause 10, wherein adjusting the geometry of the mask feature includes adjusting at least one of a shape or size of the mask feature.
   12. The computer-readable medium of clause 9, wherein the mask feature is adjusted until the cost function is minimized.
   13. The computer-readable medium of clause 1, wherein the detector is a circle.
   14. The computer-readable medium of clause 13, wherein the local feature dimension is determined based on a radius of the circle.
   15. The computer-readable medium of clause 1, wherein the local feature dimension is indicative of an interior local feature dimension when the detector is placed within the mask feature and the detector is in contact with the specified point on the edge of the mask feature.
   16. The computer-readable medium of clause 1, wherein the local feature dimension is indicative of an exterior local feature dimension when the detector is placed outside the mask feature and the detector is in contact with the specified point on the edge of another mask feature.
   17. The computer-readable medium of clause 1 further comprising:
verifying a mask design for MRC violations based on local feature dimensions of multiple mask features in the mask design.
   18. The computer-readable medium of clause 1 further comprising:
updating, based on local feature dimensions of mask features of a mask design, the mask design to determine shape or size of the mask features.
   19. The computer-readable medium of clause 18, wherein updating the mask design includes:
(a) simulating, using a design layout, a mask optimization process to determine the mask features for the mask design, the design layout corresponding to features to be printed on a substrate;
(b) determining, via the local feature dimensions, portions of the mask features that violate the MRC;
(c) responsive to violating the MRC, modifying the corresponding portions of the mask features to satisfy the MRC; and
repeating steps (a)-(c).
   20. The computer-readable medium of clause 19, the mask optimization process includes at least one of a mask only optimization process, a source mask optimization process, or an optical proximity correction process.
   21. The computer-readable medium of clause 1, wherein the mask feature is curvilinear in shape.
   22. The computer-readable medium of 1, wherein the MRC includes one or more geometric properties associated with the mask feature, the geometric properties including at least one of: a minimum CD of the mask feature that can be manufactured, a minimum curvature of the mask feature that can be manufactured, or a minimum space between two mask features that can be manufactured.
   23. A non-transitory computer-readable medium having instructions that, when executed by a computer, cause the computer to execute a method for updating a mask design to reduce mask rule check violation associated with mask features, the method comprising:
obtaining a local feature dimension associated with a mask feature of a mask design;
determining a mask rule check (MRC) violation of the mask feature based on the local feature dimension; and
adjusting, based on the local feature dimension, the mask feature to satisfy the MRC.
   24. The computer-readable medium of clause 23, wherein the MRC violation comprises a violation of a maximum critical dimension (CD).
   25. The computer-readable medium of clause 24, wherein the violation of the maximum CD occurs when the local feature dimension exceeds the maximum CD.
   26. The computer-readable medium of clause 23, wherein the MRC violation comprises a violation of a minimum CD.
   27. The computer-readable medium of clause 26, wherein the violation of the minimum CD occurs when the local feature dimension is lesser than the minimum CD.
   28. The computer-readable medium of clause 23, wherein determining the MRC violation includes:
determining the MRC violation based on the local feature dimension at multiple locations on the edge of the mask feature.
   29. The computer-readable medium of clause 23, wherein adjusting the mask feature includes:
obtaining a kernel function of the local feature dimension;
determining a cost function based on the kernel function, wherein the cost function is indicative of an extent of the MRC violation; and
obtaining a gradient of the cost function based on one or more of the cost function, the local feature dimension or a geometry of the mask feature.
   30. The computer-readable medium of clause 29 further comprising:
adjusting the mask feature based on the cost function and the gradient of the cost function to eliminate the MRC violation.
   31. The computer-readable medium of clause 30, wherein adjusting the mask feature is an iterative process in which each iteration includes:
(a) obtaining imaging properties of the mask feature;
(b) determining whether the imaging properties satisfy an imaging criterion;
(c) determining whether the mask feature satisfies MRC criterion;
(d) computing the cost function that is indicative of the MRC violation; and
(e) responsive to a determination that the imaging criterion or the MRC criterion is not satisfied, adjusting a geometry of the mask feature to reduce the cost function.
   32. The computer-readable medium of clause 31, wherein adjusting the geometry of the mask feature includes adjusting at least one of a shape or size of the mask feature
   33. The computer-readable medium of clause 30, wherein the mask feature is adjusted until the cost function is minimized.
   34. The computer-readable medium of clause 23 further comprising:
verifying the mask design for MRC violations based on local feature dimensions of multiple mask features in the mask design.
   35. The computer-readable medium of clause 23 further comprising:
updating, based on local feature dimensions of mask features of the mask design, the mask design to determine shape or size of the mask features.
   36. The computer-readable medium of clause 35, wherein updating the mask design includes:
(a) simulating, using a design layout, a mask optimization process to determine the mask features for the mask design, the design layout corresponding to features to be printed on a substrate;
(b) determining, via the local feature dimensions, portions of the mask features that violate the MRC;
(c) responsive to violating the MRC, modifying the corresponding portions of the mask features to satisfy the MRC; and
repeating steps (a)-(c).
   37. The computer-readable medium of clause 36, the mask optimization process includes at least one of a mask only optimization process, a source mask optimization process, or an optical proximity correction process.
   38. A method for determining mask rule check violation associated with mask features, the method comprising:
placing a detector at a location on an edge of a mask feature, wherein the detector is two-dimensional (2D) geometrical structure;
varying a size of the detector until the detector is in contact with a specified point, the specified point being on the edge of the mask feature or on an edge of another mask feature;
determining a local feature dimension based on the size of the detector that causes the contact with the specified point; and
determining a mask rule check (MRC) violation based on the local feature dimension.
   39. An apparatus for determining mask rule check violation associated with mask features, the apparatus comprising:
a memory storing a set of instructions; and
a processor configured to execute the set of instructions to cause the apparatus to perform a method of:
   placing a detector at a location on an edge of a mask feature, wherein the detector is two-dimensional (2D) geometrical structure;
   varying a size of the detector until the detector is in contact with a specified point, the specified point being on the edge of the mask feature or on an edge of another mask feature;
   determining a local feature dimension based on the size of the detector that causes the contact with the specified point; and
   determining a mask rule check (MRC) violation based on the local feature dimension.

The terms “optimizing” and “optimization” as used herein refers to or means adjusting a patterning apparatus (e.g., a lithography apparatus), a patterning process, etc. such that results and/or processes have more desirable characteristics, such as higher accuracy of projection of a design pattern on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. “Optimum” and other related terms should be construed accordingly. In an embodiment, optimization steps can be applied iteratively to provide further improvements in one or more metrics.

Aspects of the invention can be implemented in any convenient form. For example, an embodiment may be implemented by one or more appropriate computer programs which may be carried on an appropriate carrier medium which may be a tangible carrier medium (e.g., a disk) or an intangible carrier medium (e.g., a communications signal). Embodiments of the invention may be implemented using suitable apparatus which may specifically take the form of a programmable computer running a computer program arranged to implement a method as described herein. Thus, embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical, or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

The reader should appreciate that the present application describes several inventions. Rather than separating those inventions into multiple isolated patent applications, these inventions have been grouped into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such inventions or all aspects of such inventions.

It should be understood that the description and the drawings are not intended to limit the present disclosure to the particular form disclosed, but to the contrary, the intention is to cover all modifications, equivalents, and alternatives falling within the spirit and scope of the inventions as defined by the appended claims.

Modifications and alternative embodiments of various aspects of the inventions will be apparent to those skilled in the art in view of this description. Accordingly, this description and the drawings are to be construed as illustrative only and are for the purpose of teaching those skilled in the art the general manner of carrying out the inventions. It is to be understood that the forms of the inventions shown and described herein are to be taken as examples of embodiments. Elements and materials may be substituted for those illustrated and described herein, parts and processes may be reversed or omitted, certain features may be utilized independently, and embodiments or features of embodiments may be combined, all as would be apparent to one skilled in the art after having the benefit of this description. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an” element or “a” element includes a combination of two or more elements, notwithstanding use of other terms and phrases for one or more elements, such as “one or more.” As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. References to selection from a range includes the end points of the range.

In the above description, any processes, descriptions or blocks in flowcharts should be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art.

To the extent certain U.S. patents, U.S. patent applications, or other materials (e.g., articles) have been incorporated by reference, the text of such U.S. patents, U.S. patent applications, and other materials is only incorporated by reference to the extent that no conflict exists between such material and the statements and drawings set forth herein. In the event of such conflict, any such conflicting text in such incorporated by reference U.S. patents, U.S. patent applications, and other materials is specifically not incorporated by reference herein.

While certain embodiments have been described, these embodiments have been presented by way of example only, and are not intended to limit the scope of the present disclosures. Indeed, the novel methods, apparatuses and systems described herein can be embodied in a variety of other forms; furthermore, various omissions, substitutions, and changes in the form of the methods, apparatuses and systems described herein can be made without departing from the spirit of the present disclosures. The accompanying claims and their equivalents are intended to cover such forms or modifications as would fall within the scope and spirit of the present disclosures.

1. A non-transitory computer-readable medium having instructions that, when executed by a computer system, are configured cause the computer system to at least:
place a detector at a location on an edge of a mask feature, wherein the detector is a two-dimensional (2D) geometrical structure;
vary a size of the detector until the detector is in contact with a specified point, the specified point being on the edge of the mask feature or on an edge of another mask feature;
determine a local feature dimension based on the size of the detector that causes the contact with the specified point; and
determine a mask rule check (MRC) violation based on the local feature dimension.

2. The computer-readable medium of claim 1, wherein the MRC violation comprises a violation of a maximum critical dimension (CD) or a minimum CD.

3. The computer-readable medium of claim 1, wherein instructions configured to cause the computer system to determine the MRC violation are further configured to cause the computer system to determine the MRC violation based on the local feature dimension at multiple locations on the edge of the mask feature.

4. The computer-readable medium of claim 1, wherein the instructions are further configured to cause the computer system to:
obtain a kernel function of the local feature dimension; and
determine a cost function based on the kernel function, wherein the cost function is indicative of an extent of the MRC violation.

5. The computer-readable medium of claim 4, wherein the instructions are further configured to cause the computer system to obtain a gradient of the cost function based on one or more selected from: the cost function, the local feature dimension or a geometry of the mask feature.

6. The computer-readable medium of claim 5, wherein the instructions are further configured to cause the computer system to adjust the mask feature based on the cost function and a gradient of the cost function to eliminate the MRC violation.

7. The computer-readable medium of claim 1, wherein the detector is a circle, and wherein the local feature dimension is determined based on a radius of the circle.

8. The computer-readable medium of claim 1, wherein the local feature dimension is indicative of an interior local feature dimension when the detector is placed within the mask feature and the detector is in contact with the specified point on the edge of the mask feature.

9. The computer-readable medium of claim 1, wherein the local feature dimension is indicative of an exterior local feature dimension when the detector is placed outside the mask feature and the detector is in contact with the specified point on the edge of another mask feature.

10. The computer-readable medium of claim 1, wherein the instructions are further configured to cause the computer system to verify a mask design for MRC violations based on local feature dimensions of multiple mask features in the mask design.

11. The computer-readable medium of claim 1, wherein the instructions are further configured to cause the computer system to update, based on the determined local feature dimensions of mask features of a mask design, the mask design to determine a shape or size of the mask features.

12. The computer-readable medium of claim 10, wherein the instructions configured to cause the computer system to update the mask design are further configured to cause the computer system to:
(a) simulate, using a design layout, a mask optimization process to determine the mask features for the mask design, the design layout corresponding to features to be printed on a substrate;
(b) determine, via the local feature dimensions, portions of the mask features that violate the MRC;
(c) responsive to violation of the MRC, modify the corresponding portions of the mask features to satisfy the MRC; and
repeat steps (a)-(c).

13. The computer-readable medium of claim 12, wherein the mask optimization process includes at least one selected from: a mask only optimization process, a source mask optimization process, or an optical proximity correction process.

14. The computer-readable medium of claim 1, wherein the mask feature is curvilinear in shape.

15. The computer-readable medium of claim 1, wherein the MRC includes one or more geometric properties associated with the mask feature, the geometric properties including at least one selected from: a minimum CD of the mask feature that can be manufactured, a minimum curvature of the mask feature that can be manufactured, or a minimum space between two mask features that can be manufactured.

16. A method for determining mask rule check violation associated with mask features, the method comprising:
placing a detector at a location on an edge of a mask feature, wherein the detector is two-dimensional (2D) geometrical structure;
varying a size of the detector until the detector is in contact with a specified point, the specified point being on the edge of the mask feature or on an edge of another mask feature;
determining a local feature dimension based on the size of the detector that causes the contact with the specified point; and
determining a mask rule check (MRC) violation based on the local feature dimension.

17. The method of claim 16, further comprising:
obtaining a kernel function of the local feature dimension; and
determining a cost function based on the kernel function, wherein the cost function is indicative of an extent of the MRC violation.

18. The method of claim 16, wherein the detector is a circle, and wherein the local feature dimension is determined based on a radius of the circle.

19. The method of claim 16, wherein the local feature dimension is indicative of an interior local feature dimension when the detector is placed within the mask feature and the detector is in contact with the specified point on the edge of the mask feature and wherein the local feature dimension is indicative of an exterior local feature dimension when the detector is placed outside the mask feature and the detector is in contact with the specified point on the edge of another mask feature.

20. The method of claim 16, further comprising updating, based on the determined local feature dimensions of mask features of a mask design, the mask design to determine a shape or size of the mask features.
